(19) United States
(12) Patent Application Publication
(10) Pub. No.: US 2024/0282871 A1
(43) Pub. Date: Aug. 22, 2024

(54) SEMICONDUCTOR LIGHT-RECEIVING DEVICE

(71) Applicant: Sumitomo Electric Industries, Ltd., Osaka (JP)

(72) Inventor: Takuya OKIMOTO, Osaka-shi (JP)

(73) Assignee: Sumitomo Electric Industries, Ltd., Osaka (JP)

(21) Appl. No.: 18/442,748

(22) Filed: Feb. 15, 2024

(30) Foreign Application Priority Data
Feb. 21, 2023 (JP) 2023-025072

(51) Int. Cl. H01L 31/0352; G02B 6/122; H01L 31/0232; H01L 31/0304

(52) U.S. Cl. CPC H01L 31/0352; G02B 6/1228; H01L 31/02327; H01L 31/03046

(57) ABSTRACT

The semiconductor light-receiving device includes an input optical waveguide, a tapering optical waveguide, and a light detection unit. The input optical waveguide includes a first core and a first cladding layer, the tapering optical waveguide includes a second core and a second cladding layer. The light detection unit includes a light-absorbing layer, a first III-V compound semiconductor layer of a first conductivity type, and a second III-V compound semiconductor layer of the first conductivity type. The second III-V compound semiconductor layer has a dopant concentration higher than a dopant concentration of the first III-V compound semiconductor layer. The second core has a first thickness. The light-absorbing layer has a second thickness. The second thickness is smaller than the first thickness.

### CROSS-REFERENCE TO RELATED APPLICATIONS

This application claims priority based on Japanese Patent Application No. 2023-025072 filed on Feb. 21, 2023, and the entire contents of the Japanese patent application are incorporated herein by reference.

### BACKGROUND

### Technical Field

The present disclosure relates to a semiconductor light-receiving device.

### Background

Japanese Unexamined Patent Application Publication No. 2012-199373 discloses a light-receiving device having an input waveguide formed on a substrate, a photodiode formed on the substrate, and a tapering waveguide formed on the substrate. The tapering waveguide connects the input waveguide and the photodiode. The width of the tapering waveguide increases from the input end connected to the input waveguide toward the output end connected to the photodiode.

### SUMMARY

A semiconductor light-receiving device according to one aspect of the present disclosure includes an input optical waveguide disposed on a substrate, a tapering optical waveguide disposed on the substrate and connected to the input optical waveguide, and a light detection unit disposed on the substrate and connected to the tapering optical waveguide. The input optical waveguide includes a first core and a first cladding layer, the first core being disposed between the substrate and the first cladding layer, the tapering optical waveguide has a width increasing in a direction from the input optical waveguide toward the light detection unit, the tapering optical waveguide includes a second core and a second cladding layer, the second core being disposed between the substrate and the second cladding layer, the second core being optically coupled to the first core, the light detection unit includes a light-absorbing layer, a first III-V compound semiconductor layer of a first conductivity type, and a second III-V compound semiconductor layer of the first conductivity type, the light-absorbing layer being disposed between the substrate and the first III-V compound semiconductor layer, the first III-V compound semiconductor layer being disposed between the light-absorbing layer and the second III-V compound semiconductor layer, the light-absorbing layer being optically coupled to the second core, the second III-V compound semiconductor layer having a dopant concentration higher than a dopant concentration of the first III-V compound semiconductor layer, and the second core has a first thickness, and the light-absorbing layer has a second thickness, the second thickness being smaller than the first thickness.

### BRIEF DESCRIPTION OF THE DRAWINGS

FIG. 1 is a perspective view schematically showing a semiconductor light-receiving device according to an embodiment.

FIG. 2 is a cross-sectional view taken along line II-II of FIG. 1.

FIG. 3 is a cross-sectional view schematically showing a semiconductor light-receiving device according to another embodiment.

FIG. 4 is a cross-sectional view schematically showing a semiconductor light-receiving device according to another embodiment.

FIG. 5 is a graph showing an example of a relationship between a thickness of a light-absorbing layer and a 3 dB band.

FIG. 6 is a graph showing an example of a relationship between a thickness of a light-absorbing layer and a 3 dB band.

### DETAILED DESCRIPTION

The present disclosure provides a semiconductor light-receiving device capable of operating at high speed.

### [Description of Embodiments of Present Disclosure]

First, embodiments of the present disclosure will be listed and explained.

(1) A semiconductor light-receiving device includes an input optical waveguide disposed on a substrate, a tapering optical waveguide disposed on the substrate and connected to the input optical waveguide, and a light detection unit disposed on the substrate and connected to the tapering optical waveguide. The input optical waveguide includes a first core and a first cladding layer, the first core being disposed between the substrate and the first cladding layer, the tapering optical waveguide has a width increasing in a direction from the input optical waveguide toward the light detection unit, the tapering optical waveguide includes a second core and a second cladding layer, the second core being disposed between the substrate and the second cladding layer, the second core being optically coupled to the first core, the light detection unit includes a light-absorbing layer, a first III-V compound semiconductor layer of a first conductivity type, and a second III-V compound semiconductor layer of the first conductivity type, the light-absorbing layer being disposed between the substrate and the first III-V compound semiconductor layer, the first III-V compound semiconductor layer being disposed between the light-absorbing layer and the second III-V compound semiconductor layer, the light-absorbing layer being optically coupled to the second core, the second III-V compound semiconductor layer having a dopant concentration higher than a dopant concentration of the first III-V compound semiconductor layer, and the second core has a first thickness, and the light-absorbing layer has a second thickness, the second thickness being smaller than the first thickness.

According to the semiconductor light-receiving device, the light-absorbing layer of the light detection unit can be made thin. Since the thin light-absorbing layer reduces the transit time of the carriers, the semiconductor light-receiving device can operate at high speed.

(2) In (1), the first III-V compound semiconductor layer has a third thickness, and the second III-V compound semiconductor layer has a fourth thickness, and the third thickness may be smaller than the fourth thickness. In this case, the first III-V compound semiconductor layer of the light detection unit can be made thin. Therefore, the series resistance of the light detection unit can be reduced.

(3) In (2), the third thickness may be smaller than the second thickness.

(4) In any one of (1) to (3), at an interface between the tapering optical waveguide and the light detection unit, an upper surface of the second cladding layer may be closer to the substrate than a lower surface of the second III-V compound semiconductor layer is to the substrate. In this case, light is less likely to leak from the second core of the tapering optical waveguide to the second III-V compound semiconductor layer of the light detection unit. Accordingly, light-absorbing by the second III-V compound semiconductor layer of the light detection unit may be reduced.

(5) In any one of (1) to (4), the first cladding layer has a fifth thickness at an input end face of the input optical waveguide and a sixth thickness at an output end face of the input optical waveguide, and the sixth thickness may be smaller than the fifth thickness. In this case, the first cladding layer becomes thicker at the input end face of the input optical waveguide. Therefore, the loss of light input to the input end face can be reduced.

(6) In any one of (1) to (5), the second thickness may be 500 nm or less.

### [Details of Embodiments of Present Disclosure]

Hereinafter, embodiments of the present disclosure will be described in detail with reference to the accompanying drawings. In the description of the drawings, the same reference numerals are used for the same or equivalent elements, and redundant description is omitted. In the drawings, an XYZ coordinate system is shown as necessary. The X-axis direction, the Y-axis direction, and the Z-axis direction intersect (for example, are orthogonal to) each other.

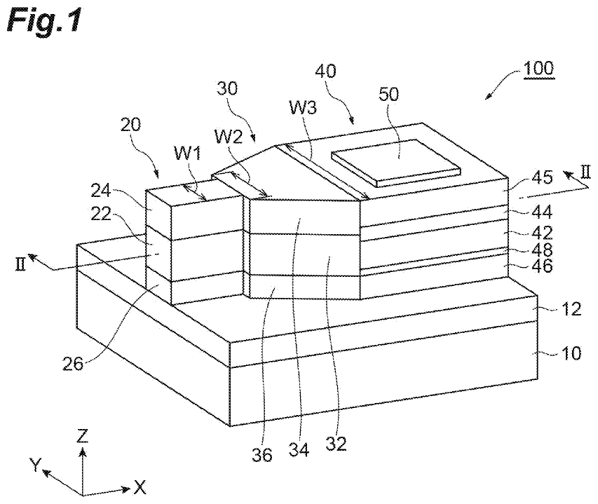

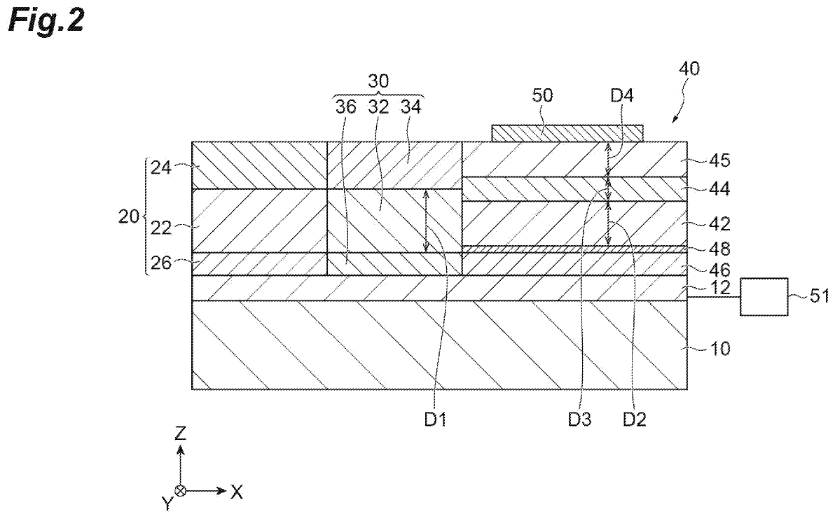

FIG. 1 is a perspective view schematically showing a semiconductor light-receiving device according to one embodiment. FIG. 2 is a cross-sectional view taken along line II-II of FIG. 1. FIG. 2 shows an XZ cross section orthogonal to the Y-axis direction. A semiconductor light-receiving device 100 shown in FIGS. 1 and 2 is used, for example, in an optical communication device having a modulation rate of 130 GBaud or higher. Semiconductor light-receiving device 100 includes an input optical waveguide 20 provided on a substrate 10, a tapering optical waveguide 30 provided on substrate 10, and a light detection unit 40 provided on substrate 10. Tapering optical waveguide 30 is connected to input optical waveguide 20. Light detection unit 40 is connected to tapering optical waveguide 30. Input optical waveguide 20, tapering optical waveguide 30, and light detection unit 40 are sequentially arranged along an optical axis direction (X-axis direction). Input optical waveguide 20 and tapering optical waveguide 30 may be in contact with each other. Tapering optical waveguide 30 and light detection unit 40 may be in contact with each other. The light input to input optical waveguide 20 travels through input optical waveguide 20 and tapering optical waveguide 30 and is detected by light detection unit 40.

Substrate 10 may be a semi-insulating III-V compound semiconductor substrate. Substrate 10 may be a semi-insulating indium phosphide (InP) substrate.

Input optical waveguide 20 may have a mesa structure. Input optical waveguide 20 extends along the X-axis direction. Input optical waveguide 20 has a width W1 (a length in the Y-axis direction) orthogonal to the X-axis direction. Input optical waveguide 20 has a height in the Z-axis direction orthogonal to the major surface of substrate 10.

Input optical waveguide 20 includes a first core 22 and a first cladding layer 24. First core 22 is disposed between substrate 10 and first cladding layer 24. The thickness of first core 22 may be 200 nm or more, or may be 600 nm or less. The thickness of first cladding layer 24 may be 800 nm or less. Input optical waveguide 20 may further include a III-V compound semiconductor layer 26 of a second conductivity type (for example, n-type). The second conductivity type is a conductivity type opposite to a first conductivity type (for example, p-type). III-V compound semiconductor layer 26 is disposed between substrate 10 and first core 22. III-V compound semiconductor layer 26 may be a buffer layer or a cladding layer. The thickness of III-V compound semiconductor layer 26 may be 500 nm or less. Adjacent members of substrate 10, III-V compound semiconductor layer 26, first core 22, and first cladding layer 24 may be in contact with each other.

First core 22 may be an i-type (non-doped) III-V compound semiconductor layer. First core 22 may include gallium indium arsenide phosphide (GaInAsP). First cladding layer 24 may include i-type InP. III-V compound semiconductor layer 26 may include InP of the second conductivity type.

Tapering optical waveguide 30 may have a mesa structure. Tapering optical waveguide 30 has a width that increases from input optical waveguide 20 toward light detection unit 40. Tapering optical waveguide 30 has a width W2 (a length in the Y-axis direction) at the input end face connected to input optical waveguide 20. Width W2 is longer than width W1. The difference between width W2 and width W1 may be 100 nm or more. Due to the difference between width W2 and width W1, higher order modes may be excited. As a result, the leakage of light in the Z-axis direction can be reduced at the interface between tapering optical waveguide 30 and light detection unit 40. Tapering optical waveguide 30 has a width W3 (length in the Y-axis direction) at the output end face connected to light detection unit 40. Width W3 is longer than width W2. Light detection unit 40 may have the same width as width W3.

Tapering optical waveguide 30 includes a second core 32 and a second cladding layer 34. Second core 32 is disposed between substrate 10 and second cladding layer 34. Second core 32 is optically coupled to first core 22. Second core 32 has a first thickness D1. First thickness D1 may be 600 nm or less, or 200 nm or more. The thickness of second cladding layer 34 may be 800 nm or less. Tapering optical waveguide 30 may further include a III-V compound semiconductor layer 36 of the second conductivity type. III-V compound semiconductor layer 36 is disposed between substrate 10 and second core 32. III-V compound semiconductor layer 36 may be a buffer layer or a cladding layer. The thickness of III-V compound semiconductor layer 36 may be 500 nm or less. Adjacent members among substrate 10, III-V compound semiconductor layer 36, second core 32, and second cladding layer 34 may be in contact with each other.

Examples of materials included in second core 32 may be the same as examples of materials included in first core 22. Examples of materials included in second cladding layer 34 may be the same as examples of materials included in first cladding layer 24. Examples of materials included in III-V compound semiconductor layer 36 may be the same as examples of materials included in III-V compound semiconductor layer 26.

Light detection unit 40 may be a PIN photodiode. Light detection unit 40 may have a mesa structure. Light detection unit 40 includes a light-absorbing layer 42, a first III-V compound semiconductor layer 44 of the first conductivity type, and a second III-V compound semiconductor layer 45 of the first conductivity type. Light-absorbing layer 42 is disposed between substrate 10 and first III-V compound semiconductor layer 44. Light-absorbing layer 42 is optically coupled to second core 32. First III-V compound semiconductor layer 44 is disposed between light-absorbing layer 42 and second III-V compound semiconductor layer 45. First III-V compound semiconductor layer 44 may be a cladding layer. Second III-V compound semiconductor layer 45 may be a contact layer. Second III-V compound semiconductor layer 45 has a dopant concentration higher than that of first III-V compound semiconductor layer 44. A dopant concentration of second III-V compound semiconductor layer 45 may be 1×10¹⁸ cm⁻³ or more.

Light-absorbing layer 42 has a second thickness D2. Second thickness D2 is smaller than first thickness D1 of second core 32. Second thickness D2 may be 500 nm or less or, may be 200 nm or more. First III-V compound semiconductor layer 44 has a third thickness D3. Third thickness D3 may be 300 nm or less or, may be 100 nm or more. Second III-V compound semiconductor layer 45 has a fourth thickness D4. Fourth thickness D4 may be 400 nm or less or, may be 100 nm or more. Third thickness D3 may be smaller than fourth thickness D4. Third thickness D3 may be smaller than second thickness D2 of light-absorbing layer 42.

Light-absorbing layer 42 may be an i-type (non-doped) III-V compound semiconductor layer. Light-absorbing layer 42 may include gallium indium arsenide (GaInAs). Examples of materials included in first III-V compound semiconductor layer 44 may be the same as examples of materials included in first cladding layer 24. Second III-V compound semiconductor layer 45 may include GaInAs.

Second III-V compound semiconductor layer 45 has an XY cross-section orthogonal to the thickness direction (Z-axis direction) of second III-V compound semiconductor layer 45. The area of the XY cross-section of second III-V compound semiconductor layer 45 may be 8 μm² or more or, may be 120 μm² or less. The XY cross-section of second III-V compound semiconductor layer 45 may have a rectangular shape. In the XY cross section of second III-V compound semiconductor layer 45, the length along the X-axis direction may be 4 μm or more or, may be 12 μm or less. In the XY cross section of second III-V compound semiconductor layer 45, the length along the Y-axis direction may be 2 μm or more or, may be 10 μm or less.

Light detection unit 40 may further include a III-V compound semiconductor layer 46 of the second conductivity type. III-V compound semiconductor layer 46 is disposed between substrate 10 and light-absorbing layer 42. III-V compound semiconductor layer 46 may be a buffer layer. The thickness of III-V compound semiconductor layer 46 may be 300 nm or less. Examples of materials included in III-V compound semiconductor layer 46 may be the same as examples of materials included in III-V compound semiconductor layer 26.

Light detection unit 40 may further include an i-type III-V compound semiconductor layer 48. III-V compound semiconductor layer 48 is disposed between III-V compound semiconductor layer 46 and light-absorbing layer 42. III-V compound semiconductor layer 48 may be a buffer layer. The thickness of III-V compound semiconductor layer 48 may be 300 nm or less. III-V compound semiconductor layer 48 may include GaInAsP.

Semiconductor light-receiving device 100 may further include a III-V compound semiconductor layer 12 of the second conductivity type. III-V compound semiconductor layer 12 is disposed between substrate 10 and light detection unit 40. III-V compound semiconductor layer 12 may be disposed between substrate 10 and input optical waveguide 20. III-V compound semiconductor layer 12 may be disposed between substrate 10 and tapering optical waveguide 30. III-V compound semiconductor layer 12 may be a contact layer. III-V compound semiconductor layer 12 has a dopant concentration higher than that of III-V compound semiconductor layer 46. A dopant concentration of III-V compound semiconductor layer 12 may be 1×10¹⁷ cm⁻³ or more. Adjacent members of substrate 10, III-V compound semiconductor layer 12, III-V compound semiconductor layer 46, III-V compound semiconductor layer 48, light-absorbing layer 42, first III-V compound semiconductor layer 44 and second III-V compound semiconductor layer 45 may be in contact with each other.

Semiconductor light-receiving device 100 may further include a first electrode 50. First electrode 50 is connected to second III-V compound semiconductor layer 45. A junction area between first electrode 50 and second III-V compound semiconductor layer 45 may be 80 μm² or less. Semiconductor light-receiving device 100 may further include a second electrode 51 connected to III-V compound semiconductor layer 12. Wiring may be connected to each of first electrode 50 and the second electrode 51. A reverse bias voltage may be applied between first electrode 50 and the second electrode 51.

In semiconductor light-receiving device 100, the series resistance between first electrode 50 and the second electrode 51 may be 60Ω (ohm) or less, or 40Ω or less. When third thickness D3 of first III-V compound semiconductor layer 44 is small, the series resistance of semiconductor light-receiving device 100 is small.

In semiconductor light-receiving device 100, the capacitance between first electrode 50 and the second electrode 51 may be 40 fF (femtofarad) or less, or 10 fF or more. When the cross-sectional area of the XY cross-section of second III-V compound semiconductor layer 45 is small, the capacitance of semiconductor light-receiving device 100 is small.

According to semiconductor light-receiving device 100, light-absorbing layer 42 of light detection unit 40 may be made thin. Since thin light-absorbing layer 42 reduces the transit time of carriers, semiconductor light-receiving device 100 can operate at a high speed. The 3 dB band of semiconductor light-receiving device 100 may be 50 GHz or more.

When third thickness D3 of first III-V compound semiconductor layer 44 is smaller than fourth thickness D4 of second III-V compound semiconductor layer 45, first III-V compound semiconductor layer 44 of light detection unit 40 may be made thin. Thus, the series resistance of semiconductor light-receiving device 100 can be reduced.

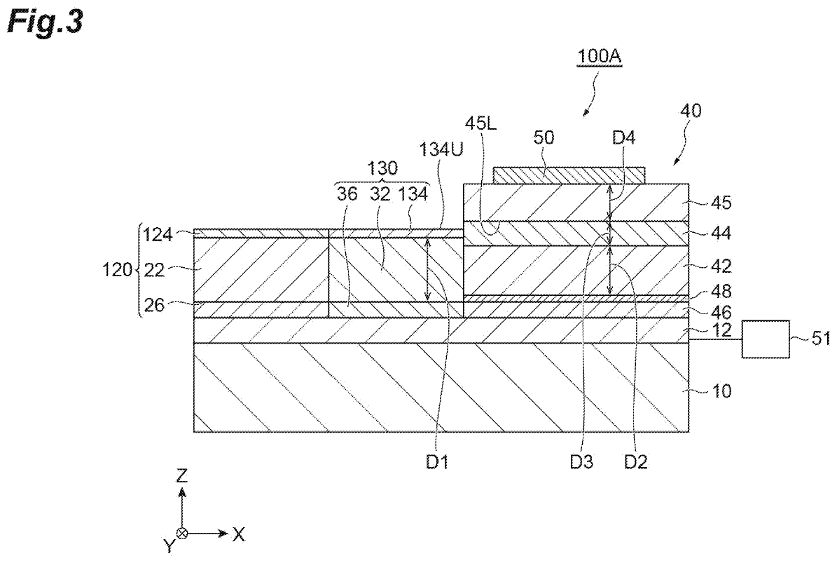

FIG. 3 is a cross-sectional view schematically showing a semiconductor light-receiving device according to another embodiment. A semiconductor light-receiving device 100A shown in FIG. 3 has the same configuration as semiconductor light-receiving device 100 except that an input optical waveguide 120 and a tapering optical waveguide 130 are provided instead of input optical waveguide 20 and tapering optical waveguide 30, respectively. Input optical waveguide 120 has the same configuration as input optical waveguide 20 except that a first cladding layer 124 is provided instead of first cladding layer 24. First cladding layer 124 is thinner than first cladding layer 24. Tapering optical waveguide 130 has the same configuration as tapering optical waveguide 30 except that a second cladding layer 134 is provided instead of second cladding layer 34. Second cladding layer 134 is thinner than second cladding layer 34. Second cladding layer 134 may have the same thickness as first cladding layer 124.

At the interface between tapering optical waveguide 130 and light detection unit 40, an upper surface 134U of second cladding layer 134 is closer to substrate 10 than a lower surface 45L of second III-V compound semiconductor layer 45. As a result, second cladding layer 134 does not contact second III-V compound semiconductor layer 45.

According to semiconductor light-receiving device 100A, the same effect as semiconductor light-receiving device 100 can be obtained. In addition, light is less likely to leak from second core 32 of tapering optical waveguide 130 to second III-V compound semiconductor layer 45 of light detection unit 40. Accordingly, light-absorbing by second III-V compound semiconductor layer 45 of light detection unit 40 may be reduced.

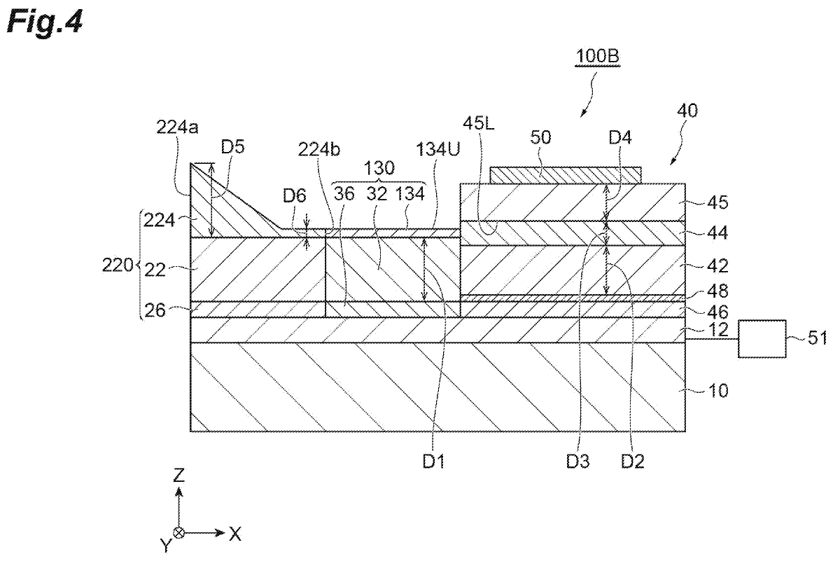

FIG. 4 is a cross-sectional view schematically showing a semiconductor light-receiving device according to another embodiment. A semiconductor light-receiving device 100B shown in FIG. 4 has the same configuration as semiconductor light-receiving device 100A except that an input optical waveguide 220 is provided instead of input optical waveguide 120. Input optical waveguide 220 has the same configuration as input optical waveguide 120 except that a first cladding layer 224 is provided instead of first cladding layer 124. First cladding layer 224 has a fifth thickness D5 at an input end face 224a of input optical waveguide 220 and a sixth thickness D6 at an output end face 224b of input optical waveguide 220. Sixth thickness D6 may be smaller than fifth thickness D5. Sixth thickness D6 may be equal to the thickness of second cladding layer 134. Input optical waveguide 220 may have a first portion including output end face 224b and a second portion including input end face 224a. The first portion of input optical waveguide 220 may have a constant thickness. The second portion of input optical waveguide 220 may have a thickness that increases from output end face 224b to input end face 224a. A recess may be formed on the surface of first cladding layer 224. Such recess can be formed by photolithography and wet etching.

According to semiconductor light-receiving device 100B, the same effect as semiconductor light-receiving device 100A can be obtained. In addition, since first cladding layer 224 is thick at input end face 224a of input optical waveguide 220, the loss of light input to input end face 224a can be reduced.

Simulations were performed on a semiconductor light-receiving device having the same structure as semiconductor light-receiving device 100. This simulation is not intended to limit the present disclosure. The simulation was performed using the following equation (1).

$$\begin{matrix}[ Equation 1 ] & \\ \frac{1}{f {1}^{2}} = \frac{1}{{f2}^{2}} + \frac{1}{f {3}^{2}} & ( 1 )\end{matrix}$$

In equation (1), f1 represents a value of a 3 dB band of the semiconductor light-receiving device. In the equation (1), f2 is expressed by the following equation (2).

$$\begin{matrix}[ Equation 2 ] & \\ f 2 ≅ \frac{3.5 v}{2 π D} & ( 2 )\end{matrix}$$

In the equation (2), v represents an average saturation velocity (5.35×10⁶ [cm/s]) of electrons and holes. D represents a thickness of the light-absorbing layer.

In the equation (1), f3 is expressed by the following equation (3).

$$\begin{matrix}[ Equation 3 ] & \\ f 3 = \frac{\sqrt{2}}{2 π C ( R L + R s )} & ( 3 )\end{matrix}$$

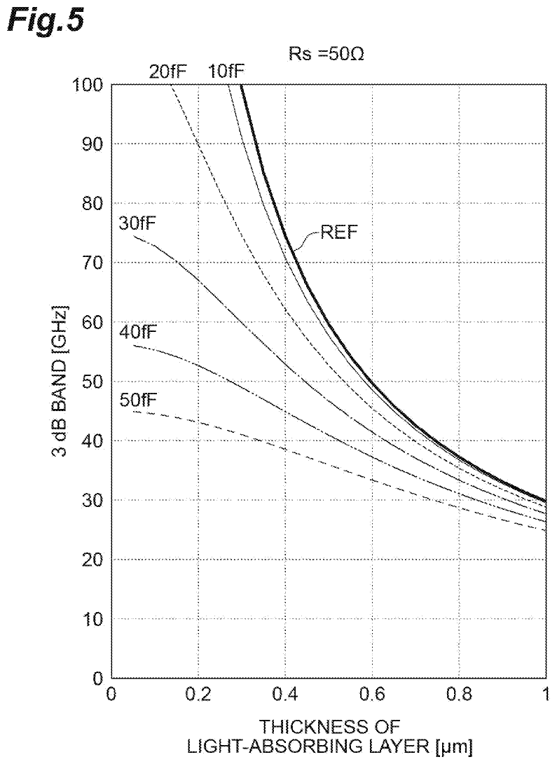

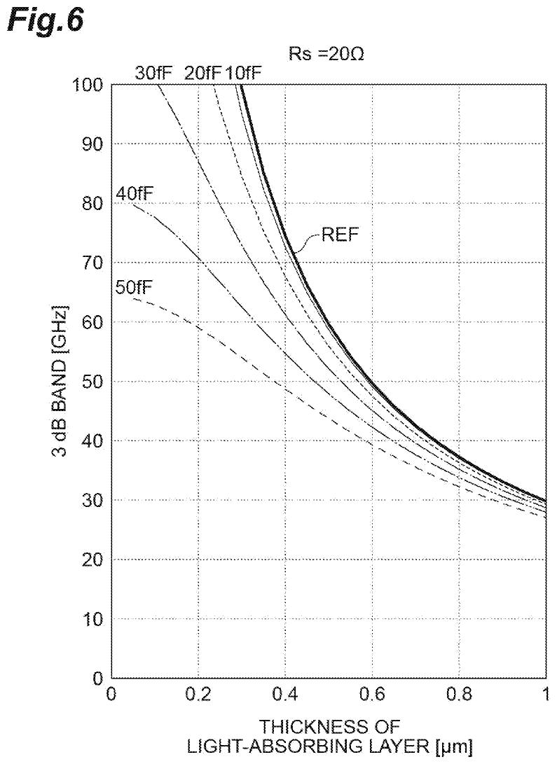

In the equation (3), C represents the capacitance of the photodiode included in the semiconductor light-receiving device. RL represents a load resistance (50Ω). Rs represents a series resistance of a photodiode included in the semiconductor light-receiving device. Rs varies in accordance with the thickness of the cladding layer on the light-absorbing layer of the photodiode. Simulation results are shown in FIG. 5 and FIG. 6.

FIGS. 5 and 6 are graphs showing examples of the relationship between the thickness of the light-absorbing layer and the 3 dB band. The horizontal axis represents the thickness (μm) of the light-absorbing layer. The vertical axis represents the 3 dB band (GHz). FIG. 5 shows a simulation result when the series resistance Rs of the photodiode is 50Ω. FIG. 6 shows a simulation result when the series resistance Rs of the photodiode is 20Ω. In each of FIGS. 5 and 6, each of 10 fF, 20 fF, 30 fF, 40 fF and 50 fF represents the capacitance C of the photodiode. Each curve represents a simulation result when the capacitance C of the photodiode has each value. In each of FIGS. 5 and 6, a reference line REF represents a simulation result when it is assumed that the capacitance C of the photodiode is 0 fF.

As shown in FIGS. 5 and 6, it can be seen that the 3 dB band increases as the capacitance of the photodiode decreases. Further, it can be seen that the 3 dB band increases as the series resistance of the photodiode decreases. In addition, it can be seen that the 3 dB band increases as the thickness of the light-absorbing layer is smaller.

It should be understood that the embodiments disclosed herein are illustrative in all respects and are not restrictive in any respect. The scope of the present invention is defined not by the above description but by the claims, and is intended to include all modifications within the meaning and scope equivalent to the claims.

What is claimed is:

1. A semiconductor light-receiving device comprising:
an input optical waveguide disposed on a substrate;
a tapering optical waveguide disposed on the substrate and connected to the input optical waveguide; and
a light detection unit disposed on the substrate and connected to the tapering optical waveguide,
wherein the input optical waveguide includes a first core and a first cladding layer, the first core being disposed between the substrate and the first cladding layer,
the tapering optical waveguide has a width increasing in a direction from the input optical waveguide toward the light detection unit,
the tapering optical waveguide includes a second core and a second cladding layer, the second core being disposed between the substrate and the second cladding layer, the second core being optically coupled to the first core,
the light detection unit includes a light-absorbing layer, a first III-V compound semiconductor layer of a first conductivity type, and a second III-V compound semiconductor layer of the first conductivity type, the light-absorbing layer being disposed between the substrate and the first III-V compound semiconductor layer, the first III-V compound semiconductor layer being disposed between the light-absorbing layer and the second III-V compound semiconductor layer, the light-absorbing layer being optically coupled to the second core, the second III-V compound semiconductor layer having a dopant concentration higher than a dopant concentration of the first III-V compound semiconductor layer, and
the second core has a first thickness, and the light-absorbing layer has a second thickness, the second thickness being smaller than the first thickness.

2. The semiconductor light-receiving device according to claim 1, wherein the first III-V compound semiconductor layer has a third thickness, and
the second III-V compound semiconductor layer has a fourth thickness, the third thickness being smaller than the fourth thickness.

3. The semiconductor light-receiving device according to claim 2, wherein the third thickness is smaller than the second thickness.

4. The semiconductor light-receiving device according to claim 2, wherein the third thickness is 300 nm or less.

5. The semiconductor light-receiving device according to claim 2, wherein the fourth thickness is 400 nm or less.

6. The semiconductor light-receiving device according to claim 1, wherein the second III-V compound semiconductor layer has a cross-section orthogonal to a thickness direction of the second III-V compound semiconductor layer, wherein an area of the cross-section is 8 μm² or more and 120 μm² or less.

7. The semiconductor light-receiving device according to claim 1, wherein the light detection unit further includes a third III-V compound semiconductor layer of a second conductivity type, the third III-V compound semiconductor layer being disposed between the substrate and the light-absorbing layer.

8. The semiconductor light-receiving device according to claim 7, wherein a thickness of the third III-V compound semiconductor layer is 300 nm or less.

9. The semiconductor light-receiving device according to claim 7, wherein the light detection unit further includes a fourth III-V compound semiconductor layer of an i-type, the fourth III-V compound semiconductor layer being disposed between the third III-V compound semiconductor layer and the light-absorbing layer.

10. The semiconductor light-receiving device according to claim 9, wherein the fourth III-V compound semiconductor layer includes GaInAsP.

11. The semiconductor light-receiving device according to claim 9, wherein a thickness of the fourth III-V compound semiconductor layer is 300 nm or less.

12. The semiconductor light-receiving device according to claim 1, wherein the light detection unit further includes a first electrode connected to the second III-V compound semiconductor layer.

13. The semiconductor light-receiving device according to claim 12, further comprising a fifth III-V compound semiconductor layer of a second conductivity type, the fifth III-V compound semiconductor layer being disposed between the substrate and the light detection unit.

14. The semiconductor light-receiving device according to claim 13, further comprising a second electrode connected to the fifth III-V compound semiconductor layer.

15. The semiconductor light-receiving device according to claim 14, wherein a series resistance between the first electrode and the second electrode is 60 ohm or less.

16. The semiconductor light-receiving device according to claim 14, wherein a capacitance between the first electrode and the second electrode is 40 femtofarad or less.

17. The semiconductor light-receiving device according to claim 12, wherein a junction area between the first electrode and the second III-V compound semiconductor layer is 80 μm² or less.

18. The semiconductor light-receiving device according to claim 1, wherein the second thickness is 500 nm or less.

19. The semiconductor light-receiving device according to claim 1, wherein at an interface between the tapering optical waveguide and the light detection unit, an upper surface of the second cladding layer is closer to the substrate than a lower surface of the second III-V compound semiconductor layer is to the substrate.

20. The semiconductor light-receiving device according to claim 1, wherein the first cladding layer has a fifth thickness at an input end face of the input optical waveguide and a sixth thickness at an output end face of the input optical waveguide, the sixth thickness being smaller than the fifth thickness.
